(19) United States
(12) Patent Application Publication
(10) Pub. No.: US 2003/0190818 A1
(43) Pub. Date: Oct. 9, 2003

(54) Enhanced processing of performance films using high-diffusivity penetrants

(76) Inventors: Ruben Carbonell, Raleigh, NC (US); Joseph M. DeSimone, Chapel Hill, NC (US); James B. McClain, Raleigh, NC (US); James DeYoung, Durham, NC (US)

Correspondence Address: MYERS BIGEL SIBLEY & SAJOVEC, PO BOX 37428, RALEIGH, NC, 27627, US

(21) Appl. No.: 10/115,352

(22) Filed: Apr. 3, 2002

(51) Int. Cl. H01L 21/31; H01L 21/469

(52) U.S. Cl. 438/760; 438/780; 438/909

(57) ABSTRACT

A method of reducing undesired topographic features, increasing film density, and/or increasing adhesion to an underlying substrate in a polymer film formed on a microelectronic substrate, comprises: (a) providing a microelectronic substrate, the substrate having a polymer film deposited thereon; (b) contacting the substrate to carbon dioxide (optionally containing additional ingredients such as cosolvents or chemical intermediates); and (c) elevating the pressure of the carbon dioxide to plasticize the polymer film and reduce undesired topographic features, increase film density, and/or increase adhesion of the film to the underlying substrate.

### FIELD OF THE INVENTION

This invention relates to methods of enhancing the performance of films formed on substrates such as microelectronic devices.

### BACKGROUND OF THE INVENTION

Liquid and supercritical carbon dioxide has been disclosed and in some cases commercially used as a diluent, carrier, or media for a variety of chemical and industrial processes ranging from fine chemical extraction and isolation to cleaning of precision parts (See, e.g., U.S. Pat. No. 5,944,966 to DeSimone et al. (cleaning); U.S. Pat. No. 6,240,936 to DeSimone et al. (spin cleaning); U.S. Pat. No. 5,858,022 to Romack et al. (dry cleaning); U.S. Pat. No. 6,120,613 to Romack et al. cleaning/separation systems)). The physical properties and the tunable nature of both liquid and supercritical CO₂, along with its generally benign nature, make it an ideal candidate for replacement of many industrial solvents and water.

Liquid and supercritical CO₂ has been disclosed as a media for coating a variety of CO₂-philic materials onto various substrates (see, e.g., U.S. Pat. No. 6,001,418 to DeSimone et al. (spin coating); U.S. Pat. No. 6,200,637 to McClain et al. (coating); U.S. Pat. No. 6,010,542 to DeYoung et al. (dyeing)). Again, the physical properties of the fluid encompassed in its tunable nature and superior wetting properties benefit a variety of applications in replacement of solvents and water.

Recently, liquid and supercritical CO₂ has been disclosed as a processing media for cleaning microelectronic substrates such as integrated circuits and MEM's devices (see, e.g., U.S. Pat. No. 5,866,005 to DeSimone et al. at column 6 lines 14-15). Typically, as proposed for cleaning semiconductor wafers during the manufacturing of integrated circuits, the CO₂ cleaning step would replace or augment conventional front end of the line (FEOL) and back end of the line (BEOL) cleaning processes that utilize solvents, reactive chemistries, and/or water. As integrated circuits are manufactured one layer at a time, typically from the silicon wafer up, each layer will go through at least one cleaning step to remove transient processing layers, etch residues, particulate mater or oxidation materials. Again, the physical properties of the CO₂ fluids, low viscosity and low surface tension, and the tunable nature provide for several benefits over conventional cleaning approaches.

Integrated circuits are typically manufactured layer by layer generally from the wafer up. Layers ranging typically from 10's of nanometers to several microns are placed one on top of the other. Some of these layers are transient such as photoresists while others such as dielectric layers make up an integral part of the finished circuitry. In all cases, exceptional film smoothness, compositional consistency, absence of transient processing components, and interlayer interfacial consistency are absolutely needed.

### SUMMARY OF THE INVENTION

A first aspect of the present invention is a method of reducing undesired topographic features, increasing film density, and/or increasing adhesion to an underlying substrate in a polymer film formed on a microelectronic substrate, the method comprising the steps of: (a) providing a preformed microelectronic substrate, the substrate having a polymer film deposited thereon; (b) contacting the substrate to carbon dioxide (optionally containing additional ingredients as discussed below) in an enclosed vessel; and (c) elevating the pressure of the carbon dioxide for a time sufficient to plasticize the polymer film and reduce undesired topographic features, increase film density (e.g., by releasing carbon dioxide or decreasing the pressure of the carbon dioxide after the elevating step), and/or increasing adhesion to said underlying substrate as compared to that previously found in the polymer film.

In general, the plasticization of the polymer results in a decrease in both viscosity and modulus, and an increase in free volume. This facilitates a film softening that results in minimization of film imperfections, and after the CO2 is released in a controlled manor the result is a densification of the polymer film.

A second aspect of the present invention is a method of accelerating a reaction in a polymer film formed on a microelectronic substrate, the method comprising the steps of: (a) providing a preformed microelectronic substrate, the substrate comprising a substrate having a polymer film deposited thereon, the film optionally containing a chemical intermediate such as a photoacid generator; (b) contacting the device to carbon dioxide (optionally containing additional ingredients as discussed below) in an enclosed vessel in the presence of at least one chemical intermediate (the chemical intermediate being in said film, in the carbon dioxide, or both) to facilitate a reaction in the polymer film; and (c) elevating the pressure of the carbon dioxide for a time sufficient to accelerate the diffusion of the at least one chemical intermediate into or in (including through) the polymer film and thereby accelerate a reaction in the polymer film.

A third aspect of the present invention is a method of accelerating the impregnation of an imaging agent into a polymer film formed on a microelectronic substrate, the method comprising the steps of: (a) providing a preformed microelectronic substrate, the substrate having a polymer film deposited thereon; (b) contacting the substrate to carbon dioxide (optionally containing additional ingredients as discussed below) in an enclosed vessel in the presence of at least one refractive element-containing imaging agent; and (c) elevating the pressure of the carbon dioxide for a time sufficient to accelerate the diffusion of the at least one refractive element-containing imaging agent into the polymer film.

The present invention may also be utilized to clean or cure films of low k dielectric materials formed on a substrate in the manner described herein.

The foregoing and other objects and aspects of the present invention are explained in greater detail below.

### DETAILED DESCRIPTION OF THE PREFERRED EMBODIMENTS

This description is not intended to be a detailed catalog of all the different ways in which the invention may be implemented, or all the features that may be added to the instant invention. For example, features illustrated with respect to one embodiment may be incorporated into other embodiments, and features illustrated with respect to a particular embodiment may be deleted from that embodiment. In addition, numerous variations and additions to the various embodiments suggested herein will be apparent to those skilled in the art in light of the instant disclosure which do not depart from the instant invention. Hence, the following specification is intended to illustrate some particular embodiments of the invention, and not to exhaustively specify all permutations, combinations and variations thereof.

Applicants specifically intend that all United States patent references cited herein be incorporated herein by reference in their entirety.

1. Definitions.

“Substrate” as used herein refers to any suitable solid substrate, often a semiconductor, used for the manufacture of microelectronic devices and the like. Suitable substrates include microelectronic substrates such as semiconductor substrates.

“Polymer films” used to carry out the present invention are formed from any suitable organic polymer. In some embodiments the polymer films are resists or photoresists. The polymer films may be of any suitable thickness, generally from 0.1 or 1 nanometers thick to 10 or 100 microns thick. The polymer films may be formed or deposited by any suitable technique, including but not limited to spin coating. The film may be formed of any suitable material, including but not limited to acrylic polymers, styrenic polymers, vinylic polymers, fluorocarbon polymers, siloxane polymers, alicyclic polymers, aromatic polymers, and mixtures thereof.

“Undesired topographic feature” as used herein with respect to polymer films refers to any undesirable topographic feature, including but not limited to open or closed pores in or on the surface of the film, waves, bumps, etc.

“Chemical reaction” as used to refer to reactions within a polymer film refers to any chemical reaction, including but not limited to neutralization reactions, condensation reactions, hydrolysis reactions, etc.

“Chemical intermediate” as used herein to refer to a compound or reagent impregnated or diffused into a polymer film to carry out or facilitate a chemical reaction includes, but is not limited to, acids, bases, catalysts, water, etc.

“Imaging agents” used to carry out the present invention include those compounds containing refractive elements, such as silylating agents.

“Plasticize” as used herein refers to the modification of a polymer containing substrate, whereby CO2 and chemical intermediates or adjuncts act to molecularly permeate the polymer and whereby the rheological properties of said polymer are changed (e.g., by decreasing viscosity and modulus).

The terms “low k dielectric material”, “low dielectric constant dielectric material”, as used herein, are intended to refer to a dielectric material having a dielectric constant below about 4, and preferably about 3.5 or less. Typically the terms “low k dielectric material” or “low dielectric constant dielectric material”, as used herein, refer to a dielectric material having a dielectric constant of from as low as about 2.5 to about 3.5.

The film of low k dielectric material formed on the substrate usually will range in thickness from about 100 or 200 nanometer (nm) to about 1,000 nm or 2,000 nm, and preferably from about 400 nm to about 800 nm, although either thinner or thicker films may be used in the process of the invention if desired. Usually the film of low k dielectric material is formed over an underlying integrated circuit structure of which it becomes a part. The film of low k dielectric material may, for example, comprise a low k carbon-doped silicon oxide dielectric material which is formed by reacting a carbon-substituted silane with a mild oxidizing agent such as hydrogen peroxide to form a film of carbon-doped low k silicon oxide dielectric material. The invention may also be useful in the treatment of other types of low k dielectric material such as hydrogen-doped or fluorinated silicon oxide dielectric films.

2. Substrates and Coatings.

The present invention will be carried out on a variety of substrates including but not limited to silicon wafers containing transient and non-transient layers applied in the manufacturing of semiconductor devices such as integrated circuits microelectromechanical devices (MEMs), optoelectronic devices. Transient layers such as photochemically active resists are typically applied by spin coating from solvent. The resist typically comprises a polymeric material, and may be a positive-acting resist or a negative-acting resist. The resist may be patterned or unpatterned, developed or undeveloped at the time the CO₂ treating process is carried out.

Any suitable resist composition can be used to carry out the present invention, including but not limited to those described in U.S. Pat. Nos. 6,042,997; 5,866,304; 5,492,793; 5,443,690; 5,071,730; 4,980,264; and 4,491,628. Applicants specifically intend that the disclosures of all United States patent references that are cited herein be incorporated herein by reference in their entirety.

The resist compositions may be applied to the substrate as a liquid compositions in accordance with generally known procedures, such as by spinning, dipping, roller coating or other conventional coating technique. When spin coating, the solids content of the coating solution can be adjusted to provide a desired film thickness based upon the specific spinning equipment utilized, the viscosity of the solution, the speed of the spinner and the amount of time allowed for spinning.

The resist compositions are suitably applied to substrates conventionally used in processes involving coating with photoresists. For example, the composition may be applied over silicon wafers (that may include one or more layers thereon such as silicon dioxide, silicon nitride, polysiloxand and/or metal, etc.) for the production of microprocessors and other integrated circuit components. Aluminum-aluminum oxide, gallium arsenide, ceramic, quartz or copper substrates also may be employed. Substrates used for liquid crystal display and other flat panel display applications are also suitably employed, e.g. glass substrates, indium tin oxide coated substrates and the like.

Other layers that can be treated by a CO₂ process disclosed in the current invention are dielectric layers used as electrical insulating layers between semiconductor and multi-level metal interconnect layers. While SiO₂ has been the predominant dielectric material in the microelectronics industry for a decade, the technological trend has been toward materials with lower dielectric constants, termed low k materials. Some of these materials are primarily inorganic in nature and still rely on chemical vapor deposition (CVD) or plasma enhanced CVD. However, a growing number of new low k materials of interest are hybrid organic/inorganic materials or wholly organic materials, and a number of these materials are applied in a spin coating process, or other solvent assisted processes.

The present invention also relates but is not limited to the treatment of semiconductor substrates containing low k films. The current invention practiced in this regard is particularly useful for substrates containing low k materials that have been applied using solvents or processing aids, or applied using processes that require a post-application treatment such as a post application bake (PAB). Low k materials that can benefit from the application of the current technology include but are not limited to: silicon, oxygen, and carbon containing polymers and polymer pre-cursors, wholly organic polymers and polymer precursors containing a predominance of carbon and hydrogen, and fluorine containing polymers and polymer precursors.

As the current invention relates to resist containing and/or low k containing semiconductor substrates, it may be practiced before, after, or in place of a post-application heat treatment step, and before and/or after a patterning step. These patterning steps incorporate photoresist developing and etch patterning steps known to those familiar with the art. The current invention may also be practice before, after, or in place of drying and cleaning steps associated with the application, curing, or patterning of resist materials and low k materials in the manufacturing of integrated circuits and the like.

3. Carbon Dioxide Compositions.

Carbon-dioxide compositions used to carry out the present invention typically comprise:

(a) carbon dioxide to balance, typically at least 40, 50 60, or 70 percent;

(b) from 0, 0.01, 0.1, 0.5, 1 or 2 percent to 5 or 10 percent or more of surfactant;

(c) from 0, 0.01, 0.1, 1 or 2 to 30, 40 or 50 percent or more of an organic co-solvent;

(d) optionally, but in some embodiments preferably, from 0, 0.01, or 0.1 to 2, 5 or 10 percent water; and

(e) optionally, but in some embodiments preferably, a chemical intermediate used to facilitate a desired chemical reaction, typically below 5% of the total composition.

Preferably at least one of the surfactant and/or the co-solvent is included (e.g., by at least 0.01 percent) in the treatment composition, and optionally both a surfactant and a co-solvent may be included in the composition. Water may or may not be included in the composition, depending upon the particular cleaning application and the nature of the substrate. Percentages herein are expressed as percentages by weight unless otherwise indicated.

The treatment composition may be provided as a liquid or supercritical fluid, including cryogenic liquids. Liquid and supercritical carbon dioxide are herein together referred to as “densified” carbon dioxide in accordance with established usage.

The organic co-solvent may be one compound or a mixture of two or more ingredients. The organic co-solvent may be or comprise an alcohol (including diols, triols, etc.), ether, amine, ketone, carbonate, or alkanes, or hydrocarbon (aliphatic or aromatic) The organic co-solvent may be a mixture of compounds, such as mixtures of alkanes as given above, or mixtures of one or more alkanes in combination with additional compounds such as one or more alcohols as described above. (e.g., from 0 or 0.1 to 5% of a C1 to C15 alcohol (including diols, triols, etc.)). Any surfactant can be used to carry out the present invention, including both surfactants that contain a CO₂-philic group (such as described in PCT Application WO96/27704) linked to a CO₂-phobic group (e.g., a lipophilic group) and surfactants that do not contain a CO₂-philic group (i.e., surfactants that comprise a hydrophilic group linked to a hydrophobic (typically lipophilic) group). A single surfactant may be used, or a combination of surfactants may be used. Numerous surfactants are known to those skilled in the art. See, e.g., McCutcheon's Volume 1: Emulsifiers & Detergents (1995 North American Edition) (MC Publishing Co., 175 Rock Road, Glen Rock, N.J. 07452). Examples of the major surfactant types that can be used to carry out the present invention include the: alcohols, alkanolamides, alkanolamines, alkylaryl sulfonates, alkylaryl sulfonic acids, alkylbenzenes, amine acetates, amine oxides, amines, sulfonated amines and amides, betaine derivatives, block polymers, carboxylated alcohol or alkylphenol ethoxylates, carboxylic acids and fatty acids, a diphenyl sulfonate derivatives, ethoxylated alcohols, ethoxylated alkylphenols, ethoxylated amines and/or amides, ethoxylated fatty acids, ethoxylated fatty esters and oils, fatty esters, fluorocarbon-based surfactants, glycerol esters, glycol esters, hetocyclic-type products, imidazolines and imidazoline derivatives, isethionates, lanolin-based derivatives, lecithin and lecithin derivatives, lignin and lignin derivatives, maleic or succinic anhydrides, methyl esters, monoglycerides and derivatives, olefin sulfonates, phosphate esters, phosphorous organic derivatives, polyethylene glycols, polymeric (polysaccharides, acrylic acid, and acrylamide) surfactants, propoxylated and ethoxylated fatty acids alcohols or alkyl phenols, protein-based surfactants, quaternary surfactants, sarcosine derivatives, silicone-based surfactants, soaps, sorbitan derivatives, sucrose and glucose esters and derivatives, sulfates and sulfonates of oils and fatty acids, sulfates and sulfonates ethoxylated alkylphenols, sulfates of alcohols, sulfates of ethoxylated alcohols, sulfates of fatty esters, sulfonates of benzene, cumene, toluene and xylene, sulfonates of condensed naphthalenes, sulfonates of dodecyl and tridecylbenzenes, sulfonates of naphthalene and alkyl naphthalene, sulfonates of petroleum, sulfosuccinamates, sulfosuccinates and derivatives, taurates, thio and mercapto derivatives, tridecyl and dodecyl benzene sulfonic acids, etc.

4. Film Treatment.

The current invention relates to the use of liquid and supercritical CO₂ in the treatment of films to enhance performance attributes or otherwise benefit the processing of thin films after application or film formation. Carbon dioxide is noted as a good plasticizer for a variety of organic polymers. Much of this is related to the superior wetting and transport properties of the fluid, particularly in the supercritical state. The following physical changes occur upon plasticization:

Polymer (film) free volume increases

Polymer (film) viscosity decreases

Polymer modulus decreases

Surface energy and contact angles at the polymer (film) interface with solids or liquids decrease

Diffusivity of molecules in the polymer (film) increases

Polymer gel transition temperature decreases

Degree of crystallinity changes

The effects of CO2 acting on thin films leading to the physical changes above can greatly enhance the properties of thin films and may replace other post film formation treatments that use high temperatures or extended periods of time to allow for molecular diffusion in the film and film flow.

It will be appreciated that the step of elevating the pressure of the carbon dioxide may be carried out concurrently with the contacting step, for example when the contacting step is carried out in an enclosed chamber.

Chemically amplified photoresists, typically organic polymers, are used extensively in manufacturing of integrated circuits as transient layers providing a framework for the construction of the circuitry layer by layer. These photoactive resist films are typically spun onto wafers from solvents. After this application step the film is typically baked: to remove residual solvent from the film, to orient the film on the wafer minimizing imperfections (holes), to increase the adhesion of the resist film with the underlying surface, to densify the film to reduce acid diffusion which can lead to distorted images. This bake step is referred to as a post application bake (PAB). After the film is exposed to the desired wavelength of light (electromagnetic radiation) through a reticle or mask exposing desired portions of the film surface to light while masking others, another bake step referred to as the post exposure bake (PEB) is used. A key reason for this step is to enhance the localized diffusion of the acid (or base) through the polymer matrix, kinetically facilitating the reaction of the light generated acid or base with the resist polymer. This is often important to eliminate standing waves in the pattern. Throughout all of these film-processing steps, heat and time are utilized to manipulate some combination of the chemistry or structure of the film. Ironically, both heat and time are detrimental to the efficient manufacturing process of high technology fabrication.

The current invention serves to augment, enhance, or otherwise replace traditional heat treatment steps providing processing benefits and/or film performance advantages. The following applications of CO₂-based film treatments are representative of the current invention.

A. Carbon dioxide based leveling of photoresist films after spin coating. In most applications of photolithography, polymer films comprising photoresist are spun-coated onto wafer substrates to produce a thin, conformal film. However, during spin coating the surface of the film can become non-ideal (non-planar and compositionally inconformal) in several ways; it can relay the topography of the underlying substrate, it can exhibit waves from modulations in spin speed, coating composition, coating deposition rate/method (evaporation), or viscosity changes, it can exhibit composition fluctuations in depth or radius based on inconsistent deposition or diffusion of various species. Correcting these inconformities often requires a planarization process, normally carried out by raising the wafer temperature. Elevation of the film's temperature lowers the film viscosity and surface tension, resulting in flow. For Example: If a spun-coat film does not adequately fill fine features on a wafer surface, a time at elevated temperature can facilitate the flow of the film, by capillary forces, into the small features on the wafer surface. Elevated temperature also could improve the surface smoothness of the film by leveling the lower viscosity (transiently so—at the elevated temperature) film.

During spin coating the surface of the film can conform to the topography of the underlying substrate. This often requires a planarization process, normally carried out by raising the wafer temperature. This lowers the film viscosity and surface tension, resulting in flow by capillary forces into the small features on the wafer surface.

Instead of raising the wafer temperature, one can raise the pressure of CO₂ above the wafer. This will cause swelling of the polymer, resulting in a significant reduction of viscosity (4 wt % CO₂ can reduce viscosity by 50%), and swelling of the film. The swelling of the film will enhance wetting of any portion that contains a pinhole defect. Lower viscosity will help the resist flow into the holes and gaps, and increase adhesion and planarity. This process would be particularly advantageous in combination with liquid CO₂-based spin coating operations with CO₂-soluble resists, or as a stand-alone process used with a conventional track system.

During conventional spin coating with water or organic solvents, about 10-20% of the film consists of residual solvents. Traditionally, the post-bake is required not only for leveling but also for removing the excess solvent. In the application of the current invention, CO₂ fluid acts on the resist film to remove excess solvent from the polymer film. The superior diffusivity of the CO₂ acting to plasticize the polymer along with the inherent solubility of the solvent in the CO₂ fluid can enhance solvent removal efficiency over traditional bake methods. This can be particularly useful for high Tg polymers, high-boiling point solvents, and for relatively thick films (>5 microns, for example).

B. Post-exposure acceleration of diffusion controlled reactions. In chemically amplified photolithography, photoacid generators or base generators are used as localized reagents for what are typically hydrolysis reactions on polymer functional groups. The change in chemical composition of the polymer creates contrast between polymer exposed to acid/base and that not exposed and is the basis for the formation of latent images upon development. The acid and base generators are photochemically activated upon exposure to light or electromagnetic radiation of a given wavelength during the exposure step. Once the acid or base is generated, reaction with the polymer functional groups is typically facilitated by the application of heat. The reaction is diffusion limited in the solid state so heat enhances the diffusion of the reagent in the polymer phase and provides the appropriate activation energy for the hydrolysis reaction. PEB also helps remove volatile hydrolysis byproducts from the resist film as they are generated during chemical amplification and helps eliminate standing waves.

The current invention discloses that dense phase carbon dioxide can be used in place of heat to facilitate diffusion-controlled reactions in thin films. The plasticization of the polymer film with CO₂ enhances the diffusion of small molecules such as acids and bases through the polymer matrix. As such, reactions such as hydrolysis reactions can be facilitated. Reaction byproducts, such as those generated during the chemical hydrolysis, can also be extracted from the film using CO₂, again without a post-exposure bake.

The current invention also discloses the use of CO₂ after application of a photoresist and PAGs to neutralize trace amounts of bases that can interfere with acid diffusion reactions. CO₂ with trace levels of water forms carbonic acid that can neutralize these trace bases. Small amounts of certain bases have been noted to result in increased T-topping with conventional lithographic treatment processes. The current invention discloses that the a post application CO₂ film treatment step in place of a PAB also benefits the performance of the film by minimizing the effects of bases.

C. Diffusion enhanced impregnation of thin films for top surface imaging. Top surface imaging is a process typically involving a silylation step whereby the resist film is treated with a silylation agent to react with functional groups, allowing selective incorporation of silicon (or other refractory elements) into the exposed or the unexposed region of the film. Incorporation into exposed or unexposed regions is dependant on the chemical functionality of the resist (positive or negative tone). Silylation is followed by a RIE oxygen plasma etch step where unprotected organic material is anisotropically etched away providing the desired feature. This technology is particularly useful for improved depth of focus over conventional photolithography techniques.

Silicon uptake, silylation, is diffusion controlled in the thin film polymer matrix. The current invention provides increased small molecule diffusion through organic films. Applied to top surface imagine the current technology can enhance the chemical uptake of intermediate silicon reagents. In summary, carbon dioxide treatment of thin films with refractory elements like silicon can be used to facilitate the diffusion in thin film polymer matrices.

D. Post-application processing and curing of low k films. Spin-on application of low k dielectric materials to form films thereof on a substrate such as a semiconductor substrate is gaining acceptance and use in the microelectronics industry (See, e.g., U.S. Pat. No. 6,346,488; U.S. Pat. No. 6,319,330). Much like with the spin-on application of photoresist, these low k dielectric material films undergo post-application processing, often including a thermal processing step to cure the film, to generate and seal porosity, and to remove unwanted application and processing residues. The current technology can be used in place of these traditional post application steps to carry out any of the treatments described herein, including but not limited to (1) orient the film at a molecular level thus curing the film, (2) drive pore generation through materials plasticization and controlled venting, (3) to remove and abate any unwanted processing materials or byproducts.

The present invention is explained in greater detail in the following non-limiting Examples.

### EXAMPLE 1

### Removal of Residual Solvent After Spin Coating Application

A 1-micron thick film of a t-butyl capped polyhydroxystyrene polymer Mn-10,500 was spin coated onto a 5-inch wafer from a 10-wt. percent solution in THF/Toluene (2:1). After a 10-minute equilibration period in dry air at 70° C., the wafer was evaluated spectroscopically to benchmark residual solvent hold-up in the film. The wafer was then added to a pressure chamber that was filled with CO2 at 1800 psi and 40° C. The chamber was maintained at 40° C. for 3 minutes while additional clean CO2 was added to the chamber and CO2 was removed from the chamber maintaining constant pressure and temperature. Over the 2-minute period, 4 fluid turnovers was achieved. The chamber was then vented to atmospheric pressure and the wafer was removed and analyzed spectroscopically. The film was determined to be essentially free of residual solvent. A second wafer, spun under identical conditions, was allowed to equilibrate in dry air at 70° C. for 10 minutes before the film was evaluated spectroscopically to benchmark solvent hold-up. The wafer was then placed on a heating plate set to 100° C. for 3-minutes. After cooling, the wafer was analyzed for residual solvent content. The film showed considerable but incomplete solvent removal. The wafer was exposed to atmospheric conditions for an additional 3-hours after which it was again evaluated spectroscopically. Solvent residue was still noted in the film.

### EXAMPLE 2

### Film Leveling After Spin Coating Application

Two identically patterned 5″ quartz wafers with non-uniform surface topography were coated with a commercially available photoresist to yield films approximately 1 micron thick. Both were allowed to equilibrate for 5 hours in dry air at 70° C. The surface topography of the films was then evaluated using a profilometer. Surface non-uniformity was seen in both wafers. One wafer was placed in a pressure vessel to which CO2 was added to 1800 psi and 50° C. The vessel was maintained at 40° C. for 3 minutes and the chamber was vented and the wafer removed. The second wafer was placed on a heating plate at 100° C. for 3 minutes then cooled. The surface of both wafers was profiled. In both cases the non-uniformity of the film was substantially reduced.

### EXAMPLE 3

### Diffusion Enhanced Chemical Reaction in a Thin Film Matrix

Two small quartz wafers were coated with a t-butyl capped polyhydroxystyrene polymer and a prototpye photoacid generator, 0.4% PAG by weight of polymer in solution. After a 70° C. PAB for 5 minutes followed by a 10-minute equilibration at 70° C., both wafers were evaluated spectroscopically to benchmark the hydroxyl content in the blanket film. Both wafers were then exposed to a light source of the desired wavelength and intensity for the same length of time. One wafer was then placed in a pressure vessel that was pressurized to 2500 psi at 50° C. for 4 minutes while CO2 was circulated through the chamber at the constant pressure and temperature. The chamber was then vented and the wafer removed. Simultaneous with the treatment of the first wafer with CO₂, the second wafer was heated to 50° C. for 4 minutes and then cooled to room temperature. Both wafers were then equilibrated in dry air for 10 minutes and then analyzed spectroscopically to determine the relative degree of hydroxyl content. While both films showed increased hydroxyl content in the film relative to the benchmark established after PAB, the film processed in the CO₂ fluid showed a substantially higher degree of hydroxyl content.

The foregoing is illustrative of the present invention, and is not to be construed as limiting thereof. The invention is defined by the following claims, with equivalents of the claims to be included therein.

That which is claimed is:

1. A method of reducing undesired topographic features in a polymer film formed on a microelectronic substrate, said method comprising the steps of:
(a) providing a preformed microelectronic substrate, said substrate having a polymer film deposited thereon;
(b) contacting said substrate to carbon dioxide in an enclosed vessel; and
(c) elevating the pressure of said carbon dioxide for a time sufficient to plasticize said polymer film and reduce undesired topographic features previously found in said polymer film.

2. The method according to claim 1, wherein said substrate is a semiconductor substrate.

3. The method according to claim 1, wherein said film is formed from a material selected from the group consisting of acrylic polymers, styrenic polymers, vinylic polymers, fluorocarbon polymers, siloxane polymers, alicyclic polymers, aromatic polymers, and mixtures thereof.

4. The method according to claim 1, wherein said film is from about 1 nanometer to 10 microns thick.

5. The method according to claim 1, wherein said film is formed by spin coating.

6. The method according to claim 1, wherein said carbon dioxide is a liquid during at least a portion of said elevating step

7. The method according to claim 1, wherein said carbon dioxide is a supercritical fluid during at least a portion of said elevating step.

8. The method according to claim 1, wherein said carbon dioxide is a gas at least 900 psi and 100° C during at least a portion of said elevating step.

9. The method according to claim 1, further comprising the step of elevating the temperature of said carbon dioxide during at least a portion of said step (c).

10. The method according to claim 1, wherein said undesireable topographic features are selected from the group consisting of pores and waves.

11. A method of increasing the density of a polymer film formed on a microelectronic substrate, said method comprising the steps of:
(a) providing a preformed microelectronic substrate, said substrate having a polymer film deposited thereon;
(b) contacting said substrate to carbon dioxide in an enclosed vessel; and
(c) elevating the pressure of said carbon dioxide for a time sufficient to plasticize said polymer film and; then
(d) optionally decreasing the pressure of said carbon dioxide to increase the density of said polymer film.

12. The method according to claim 11, wherein said substrate is a semiconductor substrate.

13. The method according to claim 11, wherein said film is formed from a material selected from the group consisting of acrylic polymers, styrenic polymers, vinylic polymers, fluorocarbon polymers, siloxane polymers, alicyclic polymers, aromatic polymers, and mixtures thereof.

14. The method according to claim 11, wherein said film is from about 1 nanometer to 10 microns thick.

15. The method according to claim 11, wherein said film is formed by spin coating.

16. The method according to claim 11, wherein said carbon dioxide is a liquid during at least a portion of said elevating step

17. The method according to claim 11, wherein said carbon dioxide is a supercritical fluid during at least a portion of said elevating step.

18. The method according to claim 11, wherein said carbon dioxide is a gas at least 900 psi and 100° C. during at least a portion of said elevating step.

19. The method according to claim 11, further comprising the step of elevating the temperature of said carbon dioxide during at least a portion of said step (c).

20. A method of enhancing the adhesion of a polymer film to a microelectronic substrate, said method comprising the steps of:
(a) providing a preformed microelectronic substrate, said substrate having a polymer film deposited thereon;
(b) contacting said substrate to carbon dioxide in an enclosed vessel; and
(c) elevating the pressure of said carbon dioxide for a time sufficient to plasticize said polymer film and enhance the adhesion of said film to said substrate.

21. The method according to claim 20, wherein said substrate is a semiconductor substrate.

22. The method according to claim 20, wherein said film is formed from a material selected from the group consisting of acrylic polymers, styrenic polymers, vinylic polymers, fluorocarbon polymers, siloxane polymers, alicyclic polymers, aromatic polymers, and mixtures thereof.

23. The method according to claim 20, wherein said film is from about 1 nanometer to 10 microns thick.

24. The method according to claim 20, wherein said film is formed by spin coating.

25. The method according to claim 20, wherein said carbon dioxide is a liquid during at least a portion of said elevating step

26. The method according to claim 20, wherein said carbon dioxide is a supercritical fluid during at least a portion of said elevating step.

27. The method according to claim 20, wherein said carbon dioxide is a gas at least 900 psi and 100° C. during at least a portion of said elevating step.

28. The method according to claim 20, further comprising the step of elevating the temperature of said carbon dioxide during at least a portion of said step (c).

29. A method of accelerating a reaction in a polymer film formed on a microelectronic substrate, said method comprising the steps of:
(a) providing a preformed microelectronic substrate, said substrate comprising a substrate having a polymer film deposited thereon;
(b) contacting said device to carbon dioxide in an enclosed vessel, with at least one chemical intermediate present in either said polymer film, said carbon dioxide, or both said polymer film and said carbon dioxide, to thereby facilitate a reaction in said polymer film; and
(c) elevating the pressure of said carbon dioxide for a time sufficient to accelerate the diffusion of said at least one chemical intermediate in said polymer film and thereby accelerate a reaction in said polymer film.

30. The method according to claim 29, wherein said chemical intermediate is contained in said carbon dioxide and is selected from the group consisting of acids, bases, catalysts, and water.

31. The method according to claim 29, wherein said reaction is a hydrolysis reaction, a condensation reaction, or a neutralization reaction.

32. The method according to claim 29, wherein said polymer film contains said chemical intermediate.

33. The method according to claim 32, wherein said chemical intermediate is a photoacid generator.

34. The method according to claim 29, wherein said substrate is a semiconductor substrate.

35. The method according to claim 29, wherein said film is formed from a material selected from the group consisting of acrylic polymers, styrenic polymers, vinylic polymers, fluorocarbon polymers, siloxane polymers, alicyclic polymers, aromatic polymers, and mixtures thereof.

36. The method according to claim 29, wherein said film is from about 1 nanometer to 10 microns thick.

37. The method according to claim 29, wherein said film is formed by spin coating.

38. The method according to claim 29, wherein said carbon dioxide is a liquid during at least a portion of said elevating step

39. The method according to claim 29, wherein said carbon dioxide is a supercritical fluid during at least a portion of said elevating step.

40. The method according to claim 29, wherein said carbon dioxide is a gas at least 900 psi and 100° C. during at least a portion of said elevating step.

41. The method according to claim 29, further comprising the step of elevating the temperature of said carbon dioxide during at least a portion of said step (c).

42. A method of accelerating the impregnation of an imaging agent into a polymer film formed on a microelectronic substrate, said method comprising the steps of:
(a) providing a preformed microelectronic substrate, said substrate having a polymer film deposited thereon;
(b) contacting said substrate to carbon dioxide in an enclosed vessel in the presence of at least one refractive element-containing imaging agent; and
(c) elevating the pressure of said carbon dioxide for a time sufficient to accelerate the diffusion of said at least one refractive element-containing imaging agent into said polymer film.

43. The method according to claim 42, wherein said refractive element-containing imaging agent is a silylating agent.

44. The method according to claim 42, wherein said substrate is a semiconductor substrate.

45. The method according to claim 42, wherein said film is formed from a material selected from the group consisting of acrylic polymers, styrenic polymers, vinylic polymers, fluorocarbon polymers, siloxane polymers, alicyclic polymers, aromatic polymers, and mixtures thereof.

46. The method according to claim 42, wherein said film is from about 1 nanometer to 10 microns thick.

47. The method according to claim 42, wherein said film is formed by spin coating.

48. The method according to claim 42, wherein said carbon dioxide is a liquid during at least a portion of said elevating step

49. The method according to claim 42, wherein said carbon dioxide is a supercritical fluid during at least a portion of said elevating step.

50. The method according to claim 42, wherein said carbon dioxide is a gas at least 900 psi and 100° C. during at least a portion of said elevating step.

51. The method according to claim 42, further comprising the step of elevating the temperature of said carbon dioxide during at least a portion of said step (c).

52. A method of cleaning a low k dielectric material film formed on a microelectronic substrate, said method comprising the steps of:
(a) providing a preformed microelectronic substrate, said substrate having a low k dielectric material film deposited thereon;
(b) contacting said substrate to carbon dioxide in an enclosed vessel; and
(c) elevating the pressure of said carbon dioxide for a time sufficient to clean said film.

53. The method according to claim 52, wherein said substrate is a semiconductor substrate.

54. The method according to claim 52, wherein said carbon dioxide is a liquid during at least a portion of said elevating step.

55. The method according to claim 52, wherein said carbon dioxide is a supercritical fluid during at least a portion of said elevating step.

56. The method according to claim 52, wherein said carbon dioxide is a gas at least 900 psi and 100° C. during at least a portion of said elevating step.

57. The method according to claim 52, further comprising the step of elevating the temperature of said carbon dioxide during at least a portion of said step (c).

58. A method of curing a low k dielectric material film formed on a microelectronic substrate, said method comprising the steps of:
(a) providing a preformed microelectronic substrate, said substrate having a low k dielectric material film deposited thereon;
(b) contacting said substrate to carbon dioxide in an enclosed vessel; and
(c) elevating the pressure of said carbon dioxide for a time sufficient to cure said film.

59. The method according to claim 58, wherein said substrate is a semiconductor substrate.

60. The method according to claim 58, wherein said carbon dioxide is a liquid during at least a portion of said elevating step.

61. The method according to claim 58, wherein said carbon dioxide is a supercritical fluid during at least a portion of said elevating step.

62. The method according to claim 58, wherein said carbon dioxide is a gas at least 900 psi and 100° C. during at least a portion of said elevating step.

63. The method according to claim 58, further comprising the step of elevating the temperature of said carbon dioxide during at least a portion of said step (c).

64. The method according to claim 58, wherein said curing step includes generating pores in said low k dielectric material film.
